(19) United States
(12) Patent Application Publication
(10) Pub. No.: US 2026/0085211 A1
(43) Pub. Date: Mar. 26, 2026

(54) POLISHING COMPOSITION

(71) Applicant: FUJIMI INCORPORATED, Aichi (JP)

(72) Inventor: Jie Lin, Tualatin, OR (US)

(21) Appl. No.: 19/215,507

(22) Filed: May 22, 2025

Related U.S. Application Data
(60) Provisional application No. 63/698,210, filed on Sep. 24, 2024.

(51) Int. Cl. C09G 1/02; C09K 3/14; H01L 21/3105

(52) U.S. Cl. CPC C09G 1/02; C09K 3/1436; H10P 95/062

(57) ABSTRACT

The present disclosure relates to chemical mechanical polishing (CMP) compositions for polishing an amorphous carbon (C) film, i.e., a hardmask. In particular, the CMP compositions include a silica abrasive, an anionic surfactant, an aluminum salt and water, combined in specified amounts to provide a composition with advantageous properties such as high C removal rate while also maintaining a low silicon removal rate.

### TECHNICAL FIELD

The present disclosure relates to chemical mechanical polishing (CMP) compositions.

### BACKGROUND

In the current and next-generation Si-based semiconductor manufacturing processes, amorphous carbon layer (ACL) hard masks are garnering considerable attention for high-aspect-ratio (HAR) etching due to their outstanding physical properties. Carbon hardmasks also play a pivotal role in achieving uniformity across wafer surfaces and enhancing the efficiency of polishing processes, such as Chemical Mechanical Polishing (CMP).

Chemical mechanical planarization or polishing (CMP) is a process in which a material is removed from a surface of a substrate, such as a silicon wafer, and the surface is planarized and polished by a physical process (e.g., abrasion, etc.) and a chemical process (e.g., oxidation, chelation, etc.). To perform the CMP process, a slurry is applied to the surface of the substrate using a CMP apparatus which is configured to perform the removal, planarization, and polishing processes. To be suitable for polishing applications, a slurry should exhibit suitable performance with respect to selectivity and removal rate, while offering some degree of control and tunability with respect to the same. The slurry should also be tunable with respect to operational pH range, type of polishing pad, etc. When the material to be removed from the surface of the substrate is a hard material such as a hardmask, conventional slurries often fail to meet the performance requirements for polishing such materials.

Thus, there is a great need to develop polishing compositions which can enhance the removal rate of amorphous carbon from wafers while at the same time minimizing any material from the film underneath, i.e., a dielectric film. These and other challenges are addressed by the subject matter disclosed herein.

### SUMMARY

In accordance with the purpose(s) of the currently disclosed subject matter or problems to be solved by the invention, as embodied and broadly described herein, it is an object of the present invention to provide a composition for polishing substrates, that facilitate an improvement in selective removal of a material from a substrate, such as an amorphous carbon film (also referred to as a carbon hardmask). Another object of the present invention is to provide a method for maintaining low removal rate of any material present in the form of additional layer(s)/film(s), i.e., a dielectric layer/film.

Accordingly, the presently disclosed subject matter in one aspect relates to a polishing composition comprising a silica abrasive, an anionic surfactant, an aluminum (Al) salt, and water, wherein the anionic surfactant is an aryl sulfonic acid-containing surfactant; and the Al salt comprises an aluminum nitrate salt, an aluminum sulfate salt, or an aluminum halide salt, wherein the polishing composition has a pH range of from about 1.0 to about 4.5.

In another aspect, the subject matter described herein is directed to a method for polishing a substrate, the method comprising the steps of: 1) providing the polishing composition as disclosed herein; 2) providing a substrate, wherein the substrate comprises a carbon-containing layer; and 3) polishing the substrate with the polishing composition to provide a polished substrate.

### DETAILED DESCRIPTION

The present invention can be understood more readily by reference to the following detailed description of the invention and the examples included therein.

Before the present compounds, compositions, articles, systems, devices, and/or methods are disclosed and described, it is to be understood that they are not limited to specific synthetic methods unless otherwise specified, or to particular components unless otherwise specified, as such may, of course, vary. It is also to be understood that the terminology used herein is for describing particular aspects only and is not intended to be limiting. Although, any methods and materials that are similar or equivalent to those described herein can be used in the practice or testing of the present invention, example methods and materials are now described.

Described herein are polishing compositions comprising a silica abrasive, an anionic surfactant, an aluminum salt and water. These polishing compositions are intended for polishing a substrate where the polishing compositions exhibit at least one benefit such as: 1) a high carbon removal rate (RR); 2) a low silicon removal rate; and 3) can be used for a substrate containing a carbon hardmask.

The high carbon removal rate, low silicon removal rate, and/or positive zeta potential of the polishing composition are key properties which can be modified as the pH of the polishing composition increases and/or as the percentage of the abrasive's surface is cationically modified.

Compositions exhibiting these key properties may be obtained by use of specific components in requisite amounts. For example, in an embodiment, a polishing composition comprising a silica abrasive, an anionic surfactant, and an aluminum salt has been found to provide a high carbon removal rate while exhibiting a low silicon removal rate, wherein the concentrations of each component of the polishing composition must be present in specific amounts to provide such removal rates.

The polishing compositions described herein are used to polish carbon hardmask-containing substrates that can optionally include a dielectric layer (e.g., a silicon-containing layer.

### A. Definitions

Listed below are definitions of various terms used to describe this invention. These definitions apply to the terms as they are used throughout this specification, unless otherwise limited in specific instances, either individually or as part of a larger group.

As used in the specification and the appended claims, the singular forms “a,” “an” and “the” include plural referents unless the context clearly dictates otherwise. Thus, for example, reference to “an abrasive” or “a pH-adjusting agent” includes mixtures of two or more such abrasives or pH-adjusting agents.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. It will also be understood that there are a number of values disclosed herein, and that each value is herein disclosed as “about” that particular value in addition to the value itself. For example, if the value “10” is disclosed, then “about 10” is also disclosed. It will also be understood that each unit between two particular units is also disclosed. For example, if 10 and 15 are disclosed, then 11, 12, 13, and 14 are also disclosed.

References in the specification and concluding claims to parts by weight of a particular element or component in a composition denote the weight relationship between the element or component and any other elements or components in the composition or article for which a part by weight is expressed. Thus, in a compound containing 2 parts by weight of component “X” and 5 parts by weight of component “Y,” “X and Y” are present at a weight ratio of 2:5 and are present in such ratio regardless of whether additional components are contained in the compositions.

A weight percent (wt. %) of a component, unless specifically stated to the contrary, is based on the total weight of the vehicle or composition in which the component is included.

As used herein, the term “hardmask” refers to a material used in semiconductor processing to protect a substrate from etching.

### B. Polishing Composition

The fundamental mechanism of CMP is to soften a surface layer by chemical reaction and then remove the softened layer by mechanical force with abrasive particles. However, the role of CMP is not only material removal, but also planarization, surface smoothening, uniformity control, defect reduction and more. Semiconductor yield enhancement is thus influenced by CMP processing. Surface scratching, which can be generated by CMP, is an extremely detrimental defect in semiconductor manufacturing. Hence, to achieve proper CMP performance without surface scratching, development of polishing compositions is crucially important. Requirements for CMP include planarized surfaces with planarity<15 nm, roughness-free surfaces with surface roughness<1 nm, defect-free surfaces with scratch and pit counts of 0 counts per wafer, are contamination free, have a high productivity, and are planarized with a high removal rate of the desired material to be removed.

The polishing compositions disclosed herein provides a high carbon removal rate while exhibiting low removal rates for silicon.

The polishing compositions described herein contain an abrasive. The abrasive grains contained in the polishing compositions according to the present invention have a positive zeta potential. Examples of such abrasive grains include a non-modified silica and a cation-modified silica (silica having cationic group). The abrasive grains are preferably a cation-modified silica (silica having cationic group), and more preferably a cation-modified colloidal silica (colloidal silica having cationic group). The abrasive grains may be used singly or in combinations of two or more thereof. Further, commercial products of the abrasive grains may be used, and synthetic products thereof may also be used.

Examples of a method for producing colloidal silica include a soda silicate method and a sol-gel method, and colloidal silica produced by any of these methods is suitably used as abrasive grains according to the present invention. However, from the viewpoint of reducing metal impurities, colloidal silica produced by a sol-gel method is preferable, since such colloidal silica produced by a sol-gel method has a low content of metal impurities diffusible in a semiconductor and corrosive ions such as chloride ions. Production of colloidal silica by such a sol-gel method can be performed by a conventionally known technique. Specifically, hydrolysis and condensation reaction are performed using a hydrolysable silicon compound (for example, alkoxysilane or a derivative thereof) as a raw material, so that colloidal silica can be obtained.

Here, the term “cation-modified” means a state in which a cationic group (for example, an amino group or a quaternary ammonium group) is bound to a surface of silica (preferably colloidal silica). Further, according to a preferred embodiment of the present invention, cation-modified silica particles are amino group-modified silica particles, and more preferably amino group-modified colloidal silica particles. According to such an embodiment, the above effect can be even more improved.

The amount of surface area of silica modified by cationic groups can vary. In some embodiments, the amount of surface area of silica modified by cationic groups is at least about 1%, at least about 1.5%, at least about 2.0%, at least about 2.2%, at least about 2.4%, at least about 3.0%, at least about 3.5%, at least about 4.0%, at least about 4.2%, or at least about 4.5% of its surface area. In addition, or in the alternative, the amount of surface area of silica modified by cationic groups is less than about 5.0%, less than about 4.7, less than about 4.6, less than about 4.5, less than about 4.0, less than about 3.5, less than about 3.0, less than about 2.8, less than about 2.5, less than about 2.4, or less than about 2.3 of its surface area. In some embodiments, the amount of surface area of silica modified by cationic groups ranges from about 2.2% to about 4.6% of its surface area. In some embodiments, the amount of surface area of silica modified by cationic groups is 4.4% of its surface area.

Silica (colloidal silica) is cationically modified by adding a silane coupling agent having a cationic group (for example, an amino group or a quaternary ammonium group) to silica (colloidal silica) for reaction at a predetermined temperature for a predetermined time period. In a preferred embodiment of the present invention, a cation-modified silica is prepared by fixing a silane coupling agent having an amino group or a silane coupling agent having a quaternary ammonium group onto the surface of silica (more preferably colloidal silica).

Examples of a silane coupling agent to be used in such a case include those described in JP 2005-162533 A. Specific examples thereof include silane coupling agents such as N-(β-aminoethyl)-γ-aminopropylmethyldimethoxysilane, N-(β-aminoethyl)-γ-aminopropyltrimethoxysilane, N-(β-aminoethyl)-γ-aminopropyltriethoxysilane, γ-aminopropyltriethoxysilane (β-aminopropyl)triethoxysilane), γ-aminopropyltrimethoxysilane, γ-triethoxysilyl-N-(α, γ-dimethyl-butylidene) propylamine, N-phenyl-γ-aminopropyltrimethoxysilane, a hydrochloride of N-(vinylbenzyl)-β-aminoethyl-γ-aminopropyltriethoxysilane, octadecyldimethyl-(γ-trimethoxysilylpropyl)-ammonium chloride, and N-trimethoxysilylpropyl-N, N, N-trimethylammonium chloride. Of these, because of good reactivity with colloidal silica, N-(β-aminoethyl)-γ-aminopropyltrimethoxysilane, N-(β-aminoethyl)-γ-aminopropyltriethoxysilane, γ-aminopropyltriethoxysilane, and γ-aminopropyltrimethoxysilane are preferably used. As described herein, one silane coupling agent may be used, or two or more thereof may be used in combination.

In addition, a silane coupling agent can be directly added to or diluted with a hydrophilic organic solvent or pure water and then added to silica (colloidal silica). Through dilution with a hydrophilic organic solvent or pure water, generation of aggregates can be suppressed. When a silane coupling agent is diluted with a hydrophilic organic solvent or pure water, the silane coupling agent may be diluted with a hydrophilic organic solvent or pure water in such a manner that the concentration of the silane coupling agent is about preferably 0.01 g or more and 1 g or less, and more preferably 0.1 g or more and 0.7 g or less in 1 L of the hydrophilic organic solvent or pure water. Examples of the hydrophilic organic solvent can include, but are not particularly limited to, lower alcohols such as methanol, ethanol, isopropanol, and butanol.

Further, through regulation of the amount of a silane coupling agent added, the amount of a cationic group to be introduced onto the surface of silica (colloidal silica) can be regulated. The amount of a silane coupling agent to be used is not particularly limited and is about preferably 0.1 mM (mmol/L) or more and 5 mM or less, and more preferably 0.5 mM or more and 3 mM or less with respect to the amount of a reaction solution.

Temperatures at which silica (colloidal silica) is cationically modified with a silane coupling agent are not particularly limited and may range from room temperature (e.g., 25° C.) to about the boiling point of a dispersing medium in which silica (colloidal silica) is dispersed. Specifically, the temperature is about 0° C. or higher and 100° C. or lower, and preferably room temperature (e.g., 25° C.) or higher and 90° C. or lower.

The lower limit of the zeta potential of the abrasive grains in the polishing composition is preferably +15 mV or more, more preferably +20 mV or more, further preferably +30 mV or more, particularly preferably +40 mV or more, and most preferably +45 mV or more. Further, the upper limit of the zeta potential of the abrasive grains in the polishing composition is preferably +60 mV or less, more preferably +50 mV or less, further preferably +40 mV or less, particularly preferably +35 mV or less, even more preferably +30 mV or less, and most preferably +20 mV or less. Specifically, the zeta potential of the abrasive grains in the polishing composition is preferably +1 mV or more and +60 mV or less, more preferably +10 mV or more and +50 mV or less, further preferably +15 mV or more and +50 mV or less, particularly preferably +20 mV or more and +50 mV or less, even more preferably +34 mV or more and +50 mV or less, and most preferably +45 mV or more and +50 mV or less.

With the abrasive grains having a positive zeta potential as described above, the carbon film can be polished at a higher polishing removal rate compared to the polishing removal rate for silicon film (selection ratio of carbon/silicon is more increased). In addition, the dispersion stability of the polishing composition can be even further enhanced.

The abrasive can have any suitable particle size. For example, the grains of the abrasive can have an average primary particle size (“PPS”) of from about 1 nm to about 100 nm, from about 10 nm to about 100 nm, from about 20 nm to about 95 nm, from about 20 nm to about 90 nm, from about 24 nm to about 90 nm, from about 30 nm to about 90 nm, from about 35 nm to about 90 nm, from about 50 nm to about 90 nm, from about 80 nm to about 90 nm, or from about 78 nm to about 90 nm. In some embodiments, the grains of the abrasive can have an average primary particle size of 90 nm.

A lower limit of the average primary particle size of the abrasive grains is preferably 20 nm or more, is more preferably 24 nm or more, is more preferably 35 nm or more, is more preferably 70 nm or more and is further preferably 74 nm or more. Further, an upper limit of the average primary particle size of the abrasive grains is preferably less than 150 nm, is more preferably 120 nm or less, is more preferably 110 nm or less, if more preferably 100 nm or less, and is further preferably 95 nm or less.

The average primary particle sizes of the abrasive grains may be measured by an FE-SEM (field emission scanning electron microscope).

The abrasive can have any suitable aggregation ratio. The aggregation ratio is calculated by the equation ((average secondary particle size)/(average primary particle size)). For example, the grains of the abrasive can have an aggregation ratio of from about 1.00 to about 5.00, from about 1.10 to about 4.50, from about 1.20 to about 4.00, from about 1.30 to about 3.50, from about 1.40 to about 3.00, from about 1.50 to about 2.50. In some embodiments, the grains of the abrasive can have an aggregation ratio of 2.42.

A lower limit of the aggregation ratio of the abrasive grains is preferably 1.00 or more, is more preferably 1.50 or more, is more preferably 2.00 or more, is more preferably 2.20 or more and is further preferably 2.30 or more. Further, an upper limit of the aggregation ratio of the abrasive grains is preferably less than 5.00, is more preferably 4.00 or less, is more preferably 3.00 or less, if more preferably 2.75 or less, and is further preferably 2.50 or less.

The average secondary particle sizes of the abrasive grains may be measured by a Dynamic Light Scattering method.

The abrasive can have any suitable surface area. For example, the abrasive can have an average BET surface area of about 30 m²/g or more, about 40 m²/g or more, about 50 m²/g or more, about 60 m²/g or more, about 70 m²/g or more, about 80 m²/g or more. Alternatively, or in addition, the abrasive can have an average surface area of about 130 m²/g or less, about 120 m²/g or less, about 110 m²/g or less, about 100 m²/g or less, about 90 m²/g or less. In some embodiments, the abrasive can have an average surface area in a range from about 10 m²/g to about 150 m²/g, from about 20 m²/g to about 140 m²/g, from about 30 m²/g to about 130 m²/g, from about 40 m²/g to about 120 m²/g, from about 50 m²/g to about 110 m²/g, from about 60 m²/g to about 100 m²/g, from about 65 m²/g to about 95 m²/g, from about 70 m²/g to about 90 m²/g, or from about 75 m²/g to about 85 m²/g, from about 30 m²/g to about 120 m²/g, from about 30 m²/g to about 110 m²/g, from about 30 m²/g to about 100 m²/g, from about 30 m²/g to about 90 m²/g, from about 30 m²/g to about 80 m²/g, from about 30 m²/g to about 70 m²/g, from about 30 m²/g to about 60 m²/g, from about 30 m²/g to about 50 m²/g, from about 30 m²/g to about 40 m²/g, from about 30 m²/g to about 35 m²/g.

The silanol group density on the silica surface of the abrasive can vary. In some embodiments, the average silanol group density on the silica surface of the abrasive grains contained in the polishing composition of the present invention is 10.0 nm⁻² or less, meaning 10 hydroxyl (—OH) groups per nm². If the average silanol group density is more than 10.0 nm⁻², hardness of the abrasive grains is low, and the polishing removal rate is accordingly lowered.

The average silanol group density on the surface of the abrasive grains is preferably 9.0 nm⁻² or less and is more preferably 8.0 nm⁻² or less and is much more preferably 7.0 nm⁻² or less. The average silanol group density on the surface of the abrasive grains is 1.0 nm⁻² or more, 2.0 nm⁻² or more, 3.0 nm⁻² or more, 4.0 nm⁻² or more, and is 5.0 nm⁻² or more.

In some embodiments, the average silanol group density on the surface of the abrasive grains is from about 1.0 nm⁻² to about 10.0 nm⁻², from about 2.0 nm⁻² to about 9.0 nm⁻², from about 3.0 nm⁻² to about 8.0 nm⁻², from about 4.0 nm⁻² to about 7.5 nm⁻², from about 5.0 nm⁻² to about 7.0 nm⁻², from about 4.0 nm⁻² to about 8.0 nm⁻², from about 5.0 nm⁻² to about 8.0 nm⁻², from about 6.0 nm⁻² to about 8.0 nm⁻².

A lower limit of the average silanol group density is generally 0.

The number of silanol groups per unit surface area of the abrasive grains can be calculated by the Sears method using neutralization titration described in “Determination of Specific Surface Area of Colloidal Silica by Titration with Sodium Hydroxide,” Analytical Chemistry, 1956, 28 (12), pp. 1982-1983, by G. W. Sears. The calculation formula for the number of silanol groups is calculated by the following equation.

$$ρ = ( c \times a \times {N}_{A} ) / ( C \times S )$$

ρ: Number of silanol groups [count/nm²]
c: Concentration of sodium hydrate solution used in titration [mol/L]
a: Amount of sodium hydrate solution having pH of 4 to 9 added dropwise [ml]
NA: Avogadro's number (6.022×10²³ [count/mol])
C: Mass of silica [g]
S: BET specific surface area [nm²/g]

The number of silanol groups per unit surface area of the abrasive grains can be controlled by selection of the method for producing abrasive grains, or the like.

The amount of abrasive present in the disclosed polishing compositions can vary. In some embodiments, the amount of abrasive in the polishing composition is about 0.001 wt. % or more, about 0.005 wt. % or more, about 0.008 wt. % or more, about 0.01 wt. % or more, about 0.05 wt. % or more, about 0.1 wt. % or more, about 0.15 wt. % or more, about 0.2 wt. % or more, or about 0.25 wt. % or more based on the total weight of the polishing composition. Alternatively, or in addition, the amount of abrasive in the polishing composition can be about 5 wt. % or less, about 4 wt. % or less, about 3 wt. % or less, about 2 wt. % or less, about 1 wt. % or less, about 0.75 wt. % or less, about 0.5 wt. % or less, about 0.45 wt. % or less, about 0.40 wt. % or less, about 0.35 wt. % or less, about 0.30 wt. % or less, about 0.25 wt. % or less, about 0.2 wt. % or less, about 0.75 wt. % or less, about 0.50 wt. % or less, about 0.25 wt. % or less, about 0.15 wt. % or less, about 0.1 wt. % or less, or about 0.075 wt. % or less based on the total weight of the polishing composition. In some embodiments, the amount of abrasive in the polishing composition can be in a range from about 0.01 wt. % to about 1 wt. %, from about 0.01 wt. % to about 0.1 wt. %, from about 0.01 wt. % to about 0.075 wt. %, or from about 0.01 wt. % to about 0.050 wt. % based on the total weight of the polishing composition.

In some embodiments, the amount of abrasive has an effect on the properties of the polishing composition, such as carbon removal rate (RR). In some embodiments, the amount of abrasive is from about 0.01 wt % to about 0.1 wt % based on the total weight of the polishing composition. In an embodiment, the amount of abrasive is about 0.05 wt % based on the total weight of the polishing composition.

While the abrasive can be of any reasonable size, the size of the abrasive influences the smoothness of the finish obtained. Precision polishing operations materials such as optical components, plastics, metals, gemstones, semiconductor components, and the like typically involve the use of abrasives with smaller sizes. For example, compositions for use in connection with precision polishing involve suspensions of abrasives with smaller average particle sizes.

In some embodiments the abrasive is colloidal silica. In some embodiments, the abrasive substantially comprises colloidal silica. As used herein, “substantially” means that 95% by weight or more, preferably 98% by weight or more, more preferably 99% by weight or more of the particles constituting the abrasive are colloidal silica, and it includes embodiments where 100% by weight of the particles are colloidal silica.

The abrasive is suspended in the compositions disclosed herein and is colloidally stable. The term colloid refers to the suspension of abrasive particles in the liquid carrier. Colloidal stability refers to the maintenance of the suspension over time. In some embodiments, the suspension is stable for at least 1, 2, 3, 4, 5, 6, or 7 days. In some embodiments, the suspension is stable for at least 1 week, at least 2 weeks, at least 3 weeks, or at least 4 weeks.

In the context of this invention, an abrasive suspension is considered colloidally stable if, when the suspension is stored at 25° C. for a time of three days, the difference between the particle size (D50) of three days stored ([D50_{3 days}] in terms of nm) and the D50 of one day stored ([D50_{1 day}] in terms of nm) is less than or equal to 0.1 (i.e., (|1−[D50_{3 days}])/[D50_{1 day}]|<0.1). The value of (|1−[D50_{3 days}]/[D50_{1 day}]|) desirably is less than or equal to 0.09, and preferably is less than or equal to 0.08.

### 1. Anionic Surfactant

The polishing composition described herein contains an anionic surfactant. In some embodiments, the anionic surfactant comprises an aryl sulfonic acid-containing surfactant. In some embodiments, the anionic surfactant comprises at least one —SO₃H moiety. In some embodiments, the anionic surfactant comprises 1, 2, 3, 4, 5, or 6 —SO₃H moieties. In some embodiments, the anionic surfactant comprises one —SO₃H moiety. In some embodiments, the anionic surfactant comprises two —SO₃H moieties. In some embodiments, the anionic surfactant comprises three —SO₃H moieties. In some embodiments, the anionic surfactant is an aryl sulfonic acid-containing surfactant of Formula (I):

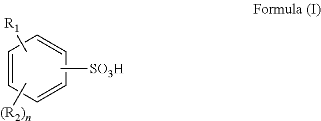

wherein
   R₁ is a C₅-C₂₀ alkyl group;
   R₂, in each instance, is selected from the group consisting of —SO₃H and

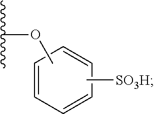

and
n is an integer selected from 0, 1, or 2.

In some embodiments, R₁ is selected from a C₆-C₁₆ alkyl group, C₆-C₁₂ alkyl group, a C₁₀-C₁₂ alkyl group, C₁₀-C₁₆ alkyl group and a C₆-C₁₀ alkyl group. In some embodiments, such alkyl groups are unbranched, i.e., straight, alkyl groups. In some embodiments, such alkyl groups are branched alkyl groups. In one embodiment, R₁ is a branched C₆-C₁₆ alkyl group. In some embodiments, R₁ is a straight C₆-C₁₆ alkyl group.

In some embodiments, R₁ is selected from a C₆ alkyl group, C₇ alkyl group, C₈ alkyl group, C₉ alkyl group, C₁₀ alkyl group, C₁₁ alkyl group, C₁₂ alkyl group, C₁₃ alkyl group, C₁₄ alkyl group, C₁₅ alkyl group, and C₁₆ alkyl group. In some embodiments, R₁ is a C₆ alkyl group. In some embodiments, R₁ is a branched C₆ alkyl group. In some embodiments, R₁ is a straight C₆ alkyl group. In some embodiments, R₁ is a C₁₀ alkyl group. In some embodiments, R₁ is a branched C₁₀ alkyl group. In some embodiments, R₁ is a straight C₁₀ alkyl group. In some embodiments, R₁ is a C₁₂ alkyl group. In some embodiments, R₁ is a branched C₁₂ alkyl group. In some embodiments, R₁ is a straight C₁₂ alkyl group.

In some embodiments, n is 0 or 1. In some embodiments, n is 0. In some embodiments, n is 1.

In some embodiments, R₂ is —SO₃H. In some embodiments, R₂ is

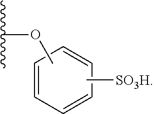

In some embodiments, n is 1 and R² is —SO₃H. In some embodiments, n is 1 and R² is

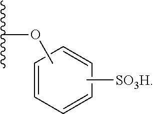

In some embodiments, n is 0 and R₁ is a C₆-C₁₆ alkyl group. In some embodiments, n is 0 and R₁ is a branched C₆-C₁₆ alkyl group. In some embodiments, n is 0 and R₁ is a branched C₁₂ alkyl group.

In some embodiments, the anionic surfactant is an aryl sulfonic acid-containing surfactant of Formula (Ia):

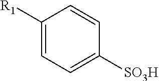

wherein R₁ is a C₆-C₁₂ alkyl group.

In some embodiments, R₁ is a branched C₆-C₁₆ alkyl group. In some embodiments, R₁ is a branched C₁₂ alkyl group. In some embodiments, R₁ is a straight C₁₂ alkyl group.

In some embodiments, n is 1 and R₁ is a C₆-C₁₆ alkyl group. In some embodiments, n is 1 and R₁ is an unbranched C₆-C₁₆ alkyl group. In some embodiments, n is 1, R₁ is an unbranched C₆-C₁₆ alkyl group, and R₂ is

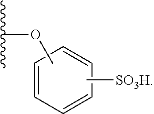

In some embodiments, n is 1, R₁ is an unbranched C₆ alkyl group, and R₂ is

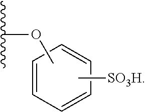

In some embodiments, n is 1, R₁ is a branched C₆-C₁₆ alkyl group, and R₂ is

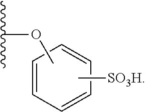

In some embodiments, R₁ is a branched C₁₂ alkyl group, and R₂ is

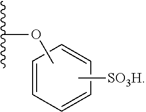

In some embodiments, the anionic surfactant is an aryl sulfonic acid-containing surfactant of Formula (Ib):

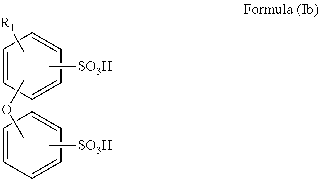

wherein R₁ is a C₆-C₁₆ alkyl group.

In some embodiments, R₁ is a branched C₁₂ alkyl group. In some embodiments, R₁ is an unbranched C₆ alkyl group.

In some embodiments, the anionic surfactant is an aryl sulfonic acid-containing surfactant selected from the group consisting of

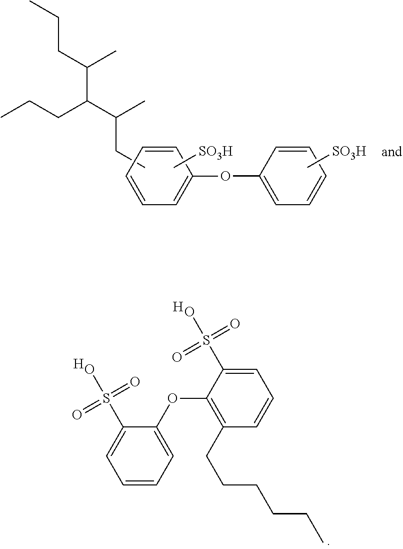

In some embodiments, n is 0 and R₁ is a C₆-C₁₆ alkyl group. In some embodiments, n is 0 and R₁ is a branched C₆-C₁₆ alkyl group. In some embodiments, n is 0 and R₁ is an unbranched C₁₂ alkyl group.

In some embodiments, the amount of the anionic surfactant can vary. In some embodiments, the amount of the anionic surfactant present in the polishing composition is in the range from about 0.0001 wt. % to about 0.1 wt. %, 0.001 wt. % to about 0.1 wt. %, or from about 0.001 wt. % to about 0.01 wt. %. In some embodiments, the amount of anionic surfactant present in the polishing composition ranges from 0.001 wt. % to about 0.01 wt. %.

In some embodiments, the amount of anionic surfactant present in the polishing composition is at least about 0.0001 wt. %, at least about 0.0005 wt. %, at least about 0.0008 wt. %, at least about 0.001 wt. %, at least about 0.005 wt. %, at least about 0.01 wt. %, or at least 0.05 wt. %. In addition, or in the alternative, the anionic surfactant can be present in the polishing composition in an amount of less than about 0.1 wt. %, less than about 0.05 wt. %, less than about 0.01 wt. %, less than about 0.005 wt. %, or less than about 0.001 wt. %.

### 2. Aluminum Salt

The polishing composition described herein contains an aluminum (Al) salt. In some embodiments, the aluminum atom within the aluminum salt has an oxidation state of +3. In some embodiments, the aluminum salt is selected from the group consisting of an aluminum (III) nitrate salt (Al(NO₃)₃), an aluminum (III) sulfate salt (Al₂(SO₄)₃), an aluminum (III) halide salt (AlX₃; X is Cl, Br, or F), and combinations thereof. In some embodiments, the aluminum salt is an aluminum (III) halide salt selected from the group consisting of aluminum (III) chloride (AlCl₃), aluminum (III) bromide (AlBr₃), and aluminum (III) fluoride (AlF₃). In some embodiments, the aluminum salt is an aluminum (III) nitrate salt, i.e., Al(NO₃)₃.

The amount of aluminum salt present in the composition can vary. In some embodiments, the amount of aluminum salt present in the polishing composition is in the range of from about 0.01 wt. % to about 1.0 wt. %, from about 0.05 wt. % to about 1.0 wt. %, from about 0.1 wt. % to about 1.0 wt. %, about 0.1 wt. % to about 0.8 wt. %, from about 0.1 wt. % to about 0.6 wt. %, from 0.1 wt. % to about 0.5 wt. %, from about 0.1 wt. % to about 0.4 wt. %, from about 0.1 wt. % to about 0.3 wt. %, from about 0.15 wt. % to about 0.25 wt. %, or from about 0.18 wt. % to about 0.22 wt. % based on the total weight of the polishing composition.

In some embodiments, the aluminum salt is present in an amount of about 0.01 wt. % or more, about 0.05 wt. % or more, about 0.1 wt. % or more, about 0.12 wt. % or more, about 0.14 wt. % or more, about 0.16 wt. % or more or about 0.18 wt. % or more based on the total weight of the polishing composition. Alternatively, or in addition, the amount of the aluminum salt is present in the polishing composition can be about 1.0 wt. % or less, about 0.9 wt. % or less, about 0.8 wt. % or less, about 0.7 wt. % or less, about 0.6 wt. % or less, about 0.5 wt. % or less, about 0.4 wt. % or less, or is about 0.3 wt. % or less based on the total weight of the polishing composition. In some embodiments, the aluminum salt is present in an amount from about 0.1 wt. % to about 1.0 wt. %, or from about 0.1 wt. % to about 0.3 wt. % based on the total weight of the polishing composition.

### 3. Water-Soluble Polymer

The polishing composition described herein may also contain a water-soluble polymer. In some embodiments, the water-soluble polymer is a nonionic polymer having a hydrophobic portion. In some embodiments, the nonionic polymer is a polymer having a polyoxyalkylene unit (POA polymer) or a polymer having a vinyl unit and a nitrogen atom (PVN polymer). In some embodiments, the water-soluble polymer is a poly (ethylene glycol) (PEG) polymer of a polyvinylpyrrolidone (PVP) polymer.

In some embodiments, the water-soluble polymer is a POA polymer. In some embodiments, the molecular weight of the POA polymer ranges from about 200 to about 6,000 g/mol, from about 200 to about 5,000 g/mol, from about 200 to about 4,000 g/mol, from about 200 to about 3,000 g/mol, from about 100 to about 2,000 g/mol, from about 200 to about 1,000 g/mol, or from about 200 to about 600 g/mol. In some embodiments, the water-soluble polymer is a PEG polymer with a molecular weight ranging from about 200 to about 400 g/mol or from about 400 to about 600 g/mol.

In some embodiments, the PEG polymer is a polymer selected from the group consisting of PEG 200, PEG 400, PEG 600 and a combination thereof. In some embodiments, the PEG polymer is a PEG 400 polymer.

In some embodiments, the water-soluble polymer is a PVN polymer. In some embodiments, the PVN polymer is a homopolymer or a copolymer. In some embodiments, the PVN polymer has a molecular weight ranging from about 2,500 to about 3,000,000 g/mol, from about 3,000 to about 1,000,000 g/mol, from about 4,000 to about 500,000 g/mol, from about 5,000 to about 50,000 g/mol, from about 6,000 to about 30,000 g/mol, from about 6,000 to about 20,000 g/mol, or from about 6,000 to about 15,000 g/mol.

In some embodiments, the water-soluble polymer is a PVP polymer. In some embodiments, the PVP polymer is a homopolymer or a copolymer. In some embodiments, the PVP polymer has a molecular weight ranging from about 2,500 to about 3,000,000 g/mol, from about 3,000 to about 1,000,000 g/mol, from about 3,500 to about 400,000 g/mol, from about 4,000 to about 50,000 g/mol, from about 4,500 to about 30,000 g/mol, from about 5,000 to about 20,000 g/mol, or from about 6,000 to about 15,000 g/mol.

In some embodiments, the PVP polymer is a polymer selected from the group consisting of PVP K-12, PVP K-15, PVP K-17, PVP, K25, PVP, K-30, PVP K-60, PVP K-90, PVP K-120 and a combination thereof.

The amount the water-soluble polymer present in the composition can vary. In some embodiments, the amount of the water-soluble polymer present in the polishing composition is in the range of from about 0.001 wt. % to about 0.1 wt. %, from about 0.001 wt. % to about 0.01 wt. %, from about 0.001 wt. % to about 0.008 wt. %, from about 0.001 wt. % to about 0.006 wt. %, from about 0.001 wt. % to about 0.003 wt. %, or from about 0.001 wt. % to about 0.002 wt. %. based on the total weight of the polishing composition. In some embodiments, amount the water-soluble polymer present in the composition ranges from about 0.001 wt. % to about 0.003 wt. %. based on the total weight of the polishing composition

In some embodiments, the amount of water-soluble polymer present in the polishing composition is at least about 0.001 wt. %, at least about 0.002 wt. %, at least about 0.003 wt. %, or at least about 0.005 wt. % based on the total weight of the polishing composition. In addition, or in the alternative, the water-soluble polymer can be present in the polishing composition in an amount of less than about 0.008 wt. %, less than about 0.007 wt. %, less than about 0.006 wt. %, less than about 0.005 wt. %, less than about 0.004 wt. %, less than about 0.003 wt. %, or less than about 0.0025 wt. % based on the total weight of the polishing composition.

### 4. pH-Adjusting Agent

The polishing compositions described herein may also contain a pH-adjusting agent. The pH-adjusting agent is not particularly limited. However, the pH of the polishing composition has a direct effect on the effectiveness of the polishing composition.

In some embodiments, the pH-adjusting agent is an acidic compound. The choice of acid is not particularly limited provided that the strength of the acid is sufficient to lower the pH of the polishing composition of the present invention. The acidic pH adjuster may be an inorganic acid or an organic acid. In some embodiments, the pH-adjusting agent is an inorganic acid.

For example, and without limitation, such inorganic acids include hydrochloric acid, sulfuric acid, nitric acid, boric acid, carbonic acid, hypo phosphorous acid, phosphorous acid, and phosphoric acid. In some embodiments, the inorganic acid is a nitric acid.

For example, and without limitation, such organic acids include formic acid, acetic acid, chloroacetic acid, propionic acid, butanoic acid, valeric acid, 2-methylbutyric acid, N-hexanoic acid, 3,3-dimethylbutanoic acid, 2-ethylbutanoic acid, 4-methylpentanoic acid, n-heptanoic acid, 2-methyl hexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citrate, citric acid, lactic acid, diglycolic acid, 2-furancarboxylic acid, 3-furancarboxylic acid, 2-tetrahydrofurancarboxylic acid, methoxyacetic acid, methoxyphenylacetic acid, and phenoxyacetic acid. Such organic acids also include, without limitation, organic sulfonic acid, such as methanesulfonic acid, ethanesulfonic acid, and isethionic acid. In some embodiments, the pH adjusting agent is citric acid.

In an alternate embodiment, the pH-adjusting agent may be a mixture of an acidic agent and basic agent (such as a buffer). In such embodiments, the base is not particularly limited and may be appropriately selected from an inorganic basic compound such as an alkali metal hydroxide, an alkaline earth metal hydroxide, various carbonates, bicarbonates and the like may be used. Such basic compounds may be used singly or in combination of two or more types thereof.

Specific examples of the alkali metal hydroxide include potassium hydroxide, sodium hydroxide, ammonium hydroxide, and the like. Specific examples of the carbonate and bicarbonate include ammonium hydrogen carbonate, ammonium carbonate, potassium hydrogen carbonate, potassium carbonate, sodium hydrogen carbonate, sodium carbonate and the like.

In an alternate embodiment, the pH-adjusting agent may be a buffer containing phosphates, acetates, borates, sulfonates, carboxylates, nitrates and the like. For example, in some embodiments, ammonium salts can be used as a buffer. Such ammonium salts include, but are not limited to, ammonium sulfates, ammonium acetates, and/or ammonium nitrates.

In some embodiments, the pH of the polishing composition is adjusted to a range from about 1.0 to about 5.0, from about 1.0 to about 4.8, from about 1.0 to about 4.5, from about 1.25 to about 4.5, from about 1.5 to about 4.5, from about 1.75 to about 4.25, from about 2.0 to about 4.0, from about 2.25 to about 4.0, from about 2.5 to about 4.0, from about 2.75 to about 3.75, from about 3.0 to about 3.75, or from about 3.25 to about 3.75. In some embodiments, the pH is less than about 5, less than about 4.75, less than about 4.5, less than about 4.25, less than about 4.0, less than about 3.75, less than about 3.50, less than about 3.0, less than about 2.5, less than about 2.0 or less than about 1.5. Alternatively, or in addition to, the pH is more than about 1.0, more than about 1.5, more than about 2.0, more than about 2.25, more than about 2.5, more than about 3.0, more than about 3.25, more than about 3.5, more than about 3.75, more than about 4.0, or more than about 4.25. In some embodiments, the pH is about from about 1.0 to about 4.5, from about 2.0 to 3.5, from about 3.0 to about 4.0, or from about 3.5 to about 4.0. In some embodiments, the pH is about 3.5.

The pH-adjusting agent may be present at a specific concentration range, regardless of pH. For example, in some embodiments, the amount of pH-adjusting agent is in a range from about 0.0001 wt. % to about 0.01 wt. %, from about 0.0001 wt. % to about 0.1 wt. %, from about 0.003 wt. % to about 0.1%, from about 0.005 wt. % to about 0.1 wt. %, from about 0.007 wt. % to about 0.1 wt. %, or from about 0.01 wt. % to about 0.1 wt. % based on the total weight of the polishing composition. In some embodiments, the amount of pH-adjusting agent is in the from about 0.01 wt. % to about 1.0 wt. %, from about 0.01 wt. % to about 0.7 wt. %, from about 0.01 wt. % to about 0.5 wt. %, or from about 0.01 wt. % to about 0.1 wt. % based on the total weight of the polishing composition. In some embodiments, the amount of pH-adjusting agent is present in an amount of at least about 0.0001 wt. %, at least about 0.001 wt. %, at least about 0.003 wt. %, at least about 0.005 wt. %, at least about 0.007 wt. %, or at least about 0.01 wt. % based on the total weight of the polishing composition. In some embodiments, the pH-adjusting agent is present in an amount of less than about 1 wt. %, less than about 0.5 wt. %, less than about 0.1 wt. %, or less than about 0.05 wt. % based on the total weight of the polishing composition. In some embodiments, the amount of pH-adjusting agent is in a range from about 0.001 wt. % to about 0.01 wt. % based on the total weight of the polishing composition,

### 5. Water

In an embodiment, the polishing compositions disclosed herein contain a carrier, medium, or vehicle. In an embodiment, the carrier, medium, or vehicle is water. Ion exchanged water (deionized water), pure water, ultrapure water, distilled water and the like may be used as the water. In order to reduce the number of unwanted components present in the water, the purity of water may be increased by operations such as removal of impurity ions with an ion exchange resin, removal of contaminants with a filter, and/or distillation.

In some embodiments, the water is relatively free of impurities. In some embodiments, the electric conductivity of the water is from about 0.05 mS/m to about 1 mS/m. In some embodiments, the total organic carbon (TOC) of the water is less than 50 ppb.

### 6. Additional Components

In an embodiment, the polishing compositions disclosed herein may contain additional components such as polymers, chelating agents, biocides, surfactants, or co-solvents. Additionally, or alternatively, the compositions disclosed herein can include other additives as will be understood by those skilled in the art.

In an embodiment, the additional component may be any material containing one or more α-glycosidic bonds. In some embodiments, such a material includes a polysaccharide. In some embodiments, the polysaccharide is water soluble. Exemplary water-soluble polysaccharides include, but are not limited to, pullulan, starch, amylose, amylopectin, gum Arabic (gum ghatti), locus bean gum (galactomannan), Konjac glucomannan, and cereal β-glucan. In some embodiments, the polysaccharide is pullulan. The amount of polysaccharide present in the polishing composition can vary. In some embodiments, the polysaccharide is present in the polishing composition in an amount 0.001 wt. % to about 0.015 wt. %, from about 0.001 wt. % to about 0.01 wt. %, from about 0.002 wt. % to about 0.008 wt. %, from about 0.004 wt. % to about 0.008 wt. %, from about 0.005 wt. % to about 0.007 wt. %. In some embodiments, the amount of polysaccharide present in the polishing composition is 0.006 wt. %.

In an embodiment, the additional component may include a chelating agent. The term chelating agent is intended to mean any substance that in the presence of an aqueous solution chelates metals, such as copper. Non-limiting examples of chelating agents include inorganic acids, organic acids, amines, and amino acids such as glycine, alanine, citric acid, acetic acid, maleic acid, oxalic acid, malonic acid, phthalic acid, succinic acid, nitrilotriacetic acid, iminodiacetic acid, ethylenediamine, DTPA, CDTA, EDTA, TTHA, HEDP, NTMP, PBTC, and EDTMP.

In an embodiment, the additional component may be a biocide. Non-limiting examples of biocides include hydrogen peroxide, quaternary ammonium compounds, and chlorine compounds. More specific examples of the quaternary ammonium compounds include, but are not limited to, methylisothiazolinone, tetramethylammonium chloride, tetraethylammonium chloride, tetrapropylammonium chloride, alkylbenzyldimethylammonium chloride, and alkylbenzyldimethylammonium hydroxide, wherein the alkyl chain ranges from 1 to about 20 carbon atoms. More specific examples of the chlorine compounds include, but are not limited to, sodium chlorite and sodium hypochlorite. Additional examples of biocides include biguanide, aldehydes, ethylene oxide, isothiazolinone, iodophor, Kordek™ MLX from DuPont (which is an aqueous composition of 2-methyl-4-isothiazolin-3-one), KATHON™ and NEOLENE™ product families that are commercially available from Dow chemicals, and the Preventol™ family from Lanxess. In an embodiment, the biocide is Kordek™ MLX. The amount of biocide used in the polishing composition may range from about 0.00005 wt. % to 0.01 wt. % or from about 0.0001 wt. % to 0.005 wt. %. In some embodiments, the biocide is present in an amount about 0.0005 wt. %, about 0.001 wt. %, or about 0.005 wt. % based on the total weight of the polishing composition.

In another embodiment, the additional component may include a surfactant. The surfactants may be anionic, cationic, nonionic, or zwitterionic and may increase lubricity of the vehicle or compositions. Non-limiting examples of the surfactants are dodecyl sulfates, sodium salts or potassium salts, lauryl sulfates, secondary alkane sulfonates, alcohol ethoxylate, acetylenic diol surfactant, quaternary ammonium-based surfactants, amphoteric surfactants, such as betaines and amino acid derivatives-based surfactants, and any combination thereof. Examples of suitable commercially available surfactants include TRITON™, TERGITOL™, and the DOWFAX™ family of surfactants manufactured by Dow Chemicals. Suitable surfactants of surfactants may also include polymers comprising ethylene oxide (EO) and propylene oxide (PO) groups. An example of EO-PO polymer is TETRONIC™ 90R₄ from BASF Chemicals. The amount of surfactant used in the polishing composition may range from about 0.0005 wt. % to 0.15 wt. %, preferably from 0.001 wt. % to 0.05 wt. %, and more preferably from 0.0025 wt. % to 0.025 wt. % based on the total weight of the polishing composition.

In another embodiment, the additional component may include another solvent, termed a co-solvent. Non-limiting examples of co-solvents include, but are not limited to, alcohol (such as methanol or ethanol), ethyl acetate, tetrahydrofuran, alkanes, tetrahydrofuran, dimethylformamide, toluene, ketones (such as acetone), aldehydes, and esters. Other non-limiting examples of co-solvents include dimethyl formamide, dimethyl sulfoxide, pyridine, acetonitrile, glycols, and mixtures thereof. The co-solvent may be employed in various amounts, preferably from a lower limit of about 0.0001, 0.001, 0.01, 0.1, 0.5, 1, 5, or 10% (wt. %) to an upper limit of about 0.001, 0.01, 0.1, 1, 5, 10, 15, 20, 25, or 35% (wt. %).

As described herein, the polishing compositions have specific properties, which are greatly influenced by the components in the composition, both in type and amount. Thus, certain materials may need to be excluded from the composition in order to maintain the desired properties.

The polishing slurries of the invention can be prepared by any suitable technique, many of which are known to those skilled in the art. The polishing composition can be prepared in a batch or a continuous process. Generally, the polishing composition can be prepared by combining the components disclosed herein in any order. The term “component” as used herein includes individual ingredients (e.g., silica abrasive, first removal rate enhancer, second removal rate enhancer, and the like), as well as any combination of ingredients. For example, the abrasive can be dispersed in water, the first and second removal rate enhancers, and any other additive material can be added, and mixed by any method that is capable of incorporating the components into the polishing composition. The pH can be further adjusted, if desired, at any suitable time by addition of an acid, base or a buffer, as needed.

Accordingly, the polishing compositions described herein have specific properties exemplified by their performance in high C removal rate and low Si removal rate.

For the polishing compositions disclosed herein, the polishing compositions have a carbon (C) removal rate (RR) of at least about 1000 Å/min; at least about 2000 Å/min; at least about 2500 Å/min; at least about 3000 Å/min; at least about 3500 Å/min; at least about 4000 Å/min; at least about 4500 Å/min; at least about 5000 Å/min; at least about 5500 Å/min; at least about 5800 Å/min; at least about 6000 Å/min, at least about 6500 Å/min, at least about 7000 Å/min, at least about 7500 Å/min, least about 7700 Å/min, at least about 8000 Å/min or at least about 8500 Å/min. In some embodiments, the polishing compositions disclosed herein have a carbon (C) removal rate (RR) of at least about 2500 Å/min.

In addition, or in the alternative, the polishing compositions disclosed herein have a carbon (C) removal rate (RR) of less than about 9000 Å/min, less than about 8800 Å/min, less than about 8000 Å/min, less than about 7710 Å/min, less than about 7500 Å/min, less than about 6000 Å/min, less than about 5500 Å/min, less than about 5000 Å/min, less than about 4500 Å/min, less than about 3000 Å/min, or less than about 2500 Å/min.

In some embodiments, the C removal rate is in a range from about 2000 Å/min to about 9000 Å/min; from about 2500 Å/min to about 8800 Å/min; from about 3800 Å/min to about 8000 Å/min; from about 4000 Å/min to about 7800 Å/min; from about 4800 Å/min to about 7750 Å/min; from about 5000 Å/min to about 7350 Å/min; or from about 5000 Å/min to about 6000 Å/min. In some embodiments, the C removal rate in a range from about 4800 Å/min to about 7710 Å/min.

For the polishing compositions disclosed herein, the polishing compositions have a silicon (Si) removal rate that is lower than the removal rate of carbon (C). In some embodiments, the silicon (Si) removal rate is less than about 200 Å/min, less than about 175 Å/min, less than about 155 Å/min, less than about 150 Å/min, less than about 125 Å/min, less than about 115 Å/min, less than about 110 Å/min, less than about 108 Å/min, less than about 105 Å/min, less than about 92 Å/min, less than about 90 Å/min, less than about 85 Å/min, less than about 80 Å/min, less than about 75 Å/min, less than about 70 Å/min, less than about 65 Å/min, less than about 60, or less than about 55 Å/min.

In addition, or in the alternative, the polishing compositions disclosed herein have a silicon (Si) removal rate that is at least about 50 Å/min, at least about 60 Å/min, at least about 65 Å/min, at least about 70 Å/min, at least about 75 Å/min, at least about 80 Å/min, at least about 85 Å/min, at least about 90 Å/min, at least about 95 Å/min, at least about 100 Å/min, at least about 105 Å/min, at least about 110 Å/min, at least about 120 Å/min at least about 130 Å/min, at least about 140 Å/min, or at least about 150 Å/min.

In some embodiments, the Si removal rate is in a range from about 50 Å/min to about 155 Å/min; from about 60 Å/min to about 110 Å/min; from about 65 Å/min to about 102 Å/min; from about 70 Å/min to about 90 Å/min; from about 75 Å/min to about 85 Å/min; from about 77 Å/min to about 85 Å/min; or from about 78 Å/min to about 84 Å/min. In some embodiments, the Si removal rate in a range from about 81 Å/min to about 87 Å/min.

For the polishing compositions disclosed herein, the polishing compositions have a C:Si removal rate (RR) ratio greater than about 20, about 25, about 30, about 35, about 40, about 45, about 50, about 55, about 60, about 65, about 70, about 75, about 80, about 85, about 90, about 95 about 100, about 105, about 110, about 115, or about 116.

In some embodiments, the C (RR):Si (RR) ratio is in a range from about 20 to about 120, from about 30 to about 116, from about 40 to about 100, from about 54 to about 95, from about 85 to about 93, from about 87 to about 93, from about 85 to about 93, or from about 90 to about 92.

Accordingly, as described herein, in some embodiments are polishing compositions comprising a silica abrasive, an anionic surfactant, an aluminum (Al) salt, and water, wherein the anionic surfactant is an aryl sulfonic acid-containing surfactant; and the Al salt comprises an aluminum nitrate salt and an aluminum sulfate salt, wherein the polishing composition has a pH ranging from about 1.0 to about 4.5.

As in any embodiment above, the polishing composition wherein the Al salt is selected from the group consisting of aluminum nitrate (III) nitrate, aluminum (III) chloride and aluminum (III) sulfate.

As in any embodiment above, the polishing composition wherein the Al salt is present in a concentration ranging from about 0.1 wt. % to about 1.0 wt. %.

As in any embodiment above, the polishing composition wherein the composition has a pH ranging from about 2.0 to about 3.5.

As in any embodiment above, the polishing composition wherein the anionic surfactant is an aryl sulfonic acid-containing surfactant of Formula (I):

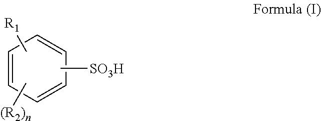

wherein
   R₁ is a C₅-C₂₀ alkyl group;
   R₂, in each instance, is selected from the group consisting of —SO₃H and

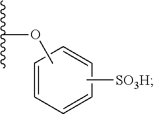

and
   n is an integer selected from 0, 1, or 2.

As in any embodiment above, the polishing composition wherein R₁ of the aryl sulfonic acid-containing surfactant of Formula (I) is a C₆-C₁₆ alkyl group.

As in any embodiment above, the polishing composition wherein C₆-C₁₆ alkyl group of the aryl sulfonic acid-containing surfactant of Formula (I) is a branched C₆-C₁₆ alkyl group.

As in any embodiment above, the polishing composition wherein C₆-C₁₆ alkyl group of the aryl sulfonic acid-containing surfactant of Formula (I) is a straight C₆-C₁₆ alkyl group.

As in any embodiment above, the polishing composition wherein n of the aryl sulfonic acid-containing surfactant of Formula (I) is 1.

As in any embodiment above, the polishing composition wherein R₂ of the aryl sulfonic acid-containing surfactant of Formula (I) is

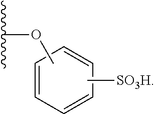

In some embodiments, the structural features of the disclosed arylsulfonic acid-containing surfactant may generally be referred to as containing a “head” portion and a “tail” portion. It would be understood that the head of the disclosed aryl sulfonic acid-containing surfactant refers to a substituted aryl sulfonic acid moiety. In some embodiments, aryl sulfonic acid-containing surfactant contains a single head portion, e.g.,

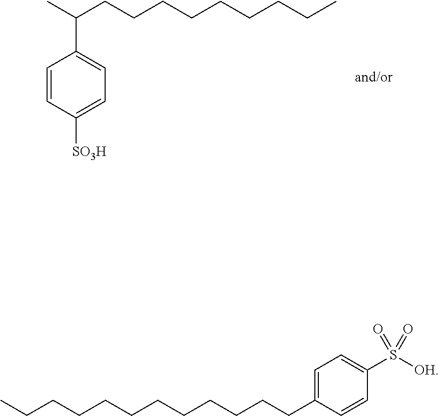

In some embodiments, the aryl sulfonic acid-containing surfactant contains two single head portions, e.g.,

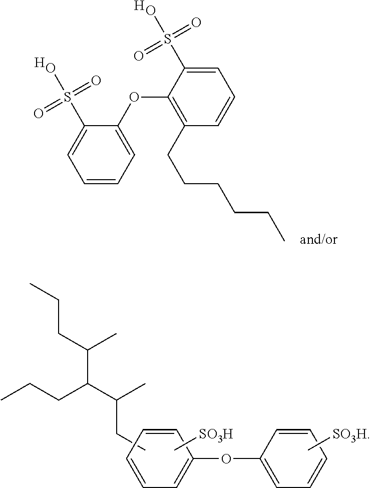

It would further be understood that the tail of the disclosed aryl sulfonic acid-containing surfactant is the alkyl chain, i.e., R₁ in the aryl sulfonic acid-containing surfactant of Formula (I).

As in any embodiment above, the polishing composition wherein the anionic surfactant is present at a concentration ranging from about 0.001 wt. % to about 0.01 wt. %.

As in any embodiment above, the polishing composition wherein the silica abrasive is a cationic-surface modified silica abrasive.

As in any embodiment above, the polishing composition wherein the cationic-surface modified abrasive has at least about 2% of its surface area modified.

As in any embodiment above, the polishing composition wherein the cationic-surface modified abrasive has about 2.2% to about 4.6% of its surface area modified.

As in any embodiment above, the polishing composition wherein the silica abrasive has an average primary particle size ranging from about 20 nm to about 90 nm.

As in any embodiment above, the polishing composition wherein the silica abrasive is present in the polishing composition at a concentration ranging from about 0.01 wt. % to about 0.1 wt. % based on the total weight of the polishing composition.

As in any embodiment above, the polishing composition wherein the silica abrasive has a positive zeta potential.

As in any embodiment above, the polishing composition wherein the silica abrasive has a zeta potential ranging from about +20 mV to about +50 mV in the polishing composition.

As in any embodiment above, the polishing composition further comprising a water-soluble polymer.

As in any embodiment above, the polishing composition wherein the water-soluble polymer is a poly(ethylene glycol) (PEG) polymer or a polyvinylpyrrolidone (PVP) polymer.

As in any embodiment above, the polishing composition wherein the PEG polymer is selected from the group consisting of PEG 200, PEG 400 and PEG 600.

As in any embodiment above, the polishing composition wherein the water-soluble polymer is present in a concentration ranging from about 0.001 wt. % to about 0.003 wt. % based on the total weight of the polishing composition.

As in any embodiment above, the polishing composition further comprising a pH-adjusting agent.

As in any embodiment above, the polishing composition wherein the pH-adjusting agent is an inorganic acid.

As in any embodiment above, the polishing composition wherein the pH-adjusting agent is nitric acid.

As in any embodiment above, the polishing composition wherein the pH-adjusting agent is present in a concentration ranging from about 0.001 wt. % to about 0.01 wt. % based on the total weight of the polishing composition.

As in any embodiment above, the polishing composition comprising a silica abrasive, an anionic surfactant, an aluminum (Al) salt, and water, wherein the anionic surfactant is present at a concentration ranging from about 0.001 wt. % to about 0.01 wt. % based on the total weight of the polishing composition and is an aryl sulfonic acid-containing surfactant selected from the group consisting of

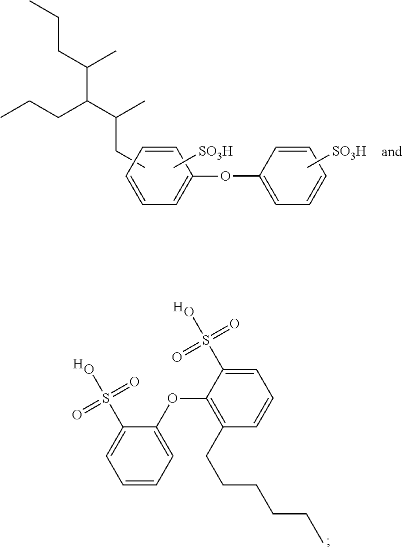

the Al salt is present at a concentration ranging from about 0.15 wt. % to about 0.25 wt. % based on the total weight of the polishing composition and is selected from the group consisting of an aluminum (III) nitrate salt, an aluminum (III) sulfate salt or an aluminum (III) chloride salt; and the silica abrasive is a cationic-surface modified abrasive with an average primary particle size ranging from about 85 nm to about 95 nm and a positive zeta potential ranging between +45 mV and +50 mV; wherein the polishing composition has a pH ranging from about 2.0 to about 3.5.

As in any embodiment above, the polishing composition wherein the Al salt is aluminum (III) nitrate.

As in any embodiment above, the polishing composition wherein the cationic-surface modified abrasive has about 4.2 to about 4.6 of its surface area modified.

As in any embodiment above, the polishing composition further comprising a PEG 400 polymer in an amount ranging from about 0.001 wt. % to about 0.003 wt. % based on the total weight of the polishing composition.

As in any embodiment above, the polishing composition wherein the composition has a carbon removal rate of at least about 2500 Å/min.

As in any embodiment above, the polishing composition wherein the composition has a silicon removal rate of less than about 150 Å/min.

As in any embodiment above, the polishing composition wherein the composition has a carbon removal rate:silicon removal rate selectivity ratio of greater than 50.

### C. Methods of Using the Polishing Compositions

The polishing compositions described herein are useful for polishing any suitable substrate. In an embodiment, the substrate to be polished can be any suitable substrate, which comprises at least one layer of carbon (C), e.g., amorphous carbon and/or spin-on carbon. In another embodiment, the polishing composition can be used to polish a substrate comprising a carbon layer. In some embodiments, such a carbon layer is comprised in a carbon hardmask (HCM)

Suitable substrates include, but are not limited to, flat panel displays, integrated circuits, memory or rigid disks, metals, semiconductors, ILD devices, microelectromechanical systems (MEMS), ferroelectrics, and magnetic heads.

In some embodiments, the substrate may further comprise at least one other layer. In some embodiments, the other layer contains one or more dielectric materials. In some embodiments, the other layer contains silicon (Si), e.g., amorphous silicon.

In some embodiments, the substrate can further comprise at least one other layer, e.g., an insulating layer. The insulating layer can be a metal oxide, glass, organic polymer, or any other suitable high- or low-K insulating layer. The insulating layer can comprise, consist essentially of, or consist of silicon oxide, SiN, or combinations thereof. The silicon oxide layer can comprise, consist essentially of, or consist of any suitable silicon oxide, many of which are known in the art. For example, the silicon oxide layer can comprise tetraethoxysilane (TEOS), high density plasma (HDP) oxide, borophosphosilicate glass (BPSG), high aspect ratio process (HARP) oxide, spin-on dielectric (SOD) oxide, chemical vapor deposition (CVD) oxide, plasma-enhanced tetraethyl orthosilicate (PETEOS), thermal oxide, or undoped silicate glass.

The subject matter disclosed herein also comprises a method for polishing a substrate with the polishing compositions described herein. The method of polishing a substrate comprises: (a) providing a substrate, (b) providing a polishing composition described herein, (c) applying the polishing composition to at least a portion of the substrate, and (d) abrading at least a portion of the substrate with the polishing composition to polish the substrate.

In the method of polishing a substrate, the polishing compositions disclosed herein have a carbon (C) removal rate (RR) of at least about 1000 Å/min; at least about 2000 Å/min; at least about 2500 Å/min; at least about 3000 Å/min; at least about 3500 Å/min; at least about 4000 Å/min; at least about 4500 Å/min; at least about 5000 Å/min; at least about 5500 Å/min; at least about 5800 Å/min; at least about 6000 Å/min, at least about 6500 Å/min, at least about 7000 Å/min, at least about 7500 Å/min, least about 7700 Å/min, at least about 8000 Å/min or at least about 8500 Å/min. In some embodiments, the polishing compositions disclosed herein have a carbon (C) removal rate (RR) of at least about 2500 Å/min. In addition, or in the alternative, the polishing compositions disclosed in the polishing methods herein have a carbon (C) removal rate (RR) of less than about 9000 Å/min, less than about 8800 Å/min, less than about 8000 Å/min, less than about 7710 Å/min, less than about 7500 Å/min, less than about 6000 Å/min, less than about 5500 Å/min, less than about 5000 Å/min, less than about 4500 Å/min, less than about 3000 Å/min, or less than about 2500 Å/min. In some embodiments, the C removal rate of the polishing compositions of the methods disclosed herein is in a range from about 2000 Å/min to about 9000 Å/min; from about 2500 Å/min to about 8800 Å/min; from about 3800 Å/min to about 8000 Å/min; from about 4000 Å/min to about 7800 Å/min; from about 4800 Å/min to about 7750 Å/min; from about 5000 Å/min to about 7350 Å/min; or from about 5000 Å/min to about 6000 Å/min. In some embodiments, the C removal rate in a range from about 4800 Å/min to about 7710 Å/min.

In the method of polishing a substrate, the polishing compositions disclosed herein have a silicon (Si) removal rate that is lower than the removal rate of carbon (C). In some embodiments, the silicon (Si) removal rate is less than about 200 Å/min, less than about 175 Å/min, less than about 155 Å/min, less than about 150 Å/min, less than about 125 Å/min, less than about 115 Å/min, less than about 110 Å/min, less than about 108 Å/min, less than about 105 Å/min, less than about 92 Å/min, less than about 90 Å/min, less than about 85 Å/min, less than about 80 Å/min, less than about 75 Å/min, less than about 70 Å/min, less than about 65 Å/min, less than about 60, or less than about 55 Å/min. In addition, or in the alternative, the polishing compositions of the methods disclosed herein have a silicon (Si) removal rate that is at least about 50 Å/min, at least about 60 Å/min, at least about 65 m at least about 70 Å/min, at least about 75 Å/min, at least about 80 Å/min, at least about 85 Å/min, at least about 90 Å/min, at least about 95 Å/min, at least about 100 Å/min, at least about 105 Å/min, at least about 110 Å/min, at least about 120 Å/min at least about 130 Å/min, at least about 140 Å/min, or at least about 150 Å/min. In some embodiments, the Si removal rate of the polishing compositions used in the methods disclosed herein is in a range from about 50 Å/min to about 155 Å/min; from about 60 Å/min to about 110 Å/min; from about 65 Å/min to about 102 Å/min; from about 70 Å/min to about 90 Å/min; from about 75 Å/min to about 85 Å/min; from about 77 Å/min to about 85 Å/min; or from about 78 Å/min to about 84 Å/min. In some embodiments, the Si removal rate in a range from about 81 Å/min to about 87 Å/min.

In the method of polishing a substrate, the polishing compositions disclosed herein have a C:Si removal rate (RR) ratio greater than about 20, about 25, about 30, about 35, about 40, about 45, about 50, about 55, about 60, about 65, about 70, about 75, about 80, about 85, about 90, about 95 about 100, about 105, about 110, about 115, or about 116.

In some embodiments, the C (RR):Si (RR) ratio is in a range from about 20 to about 120, from about 30 to about 116, from about 40 to about 100, from about 54 to about 95, from about 85 to about 93, from about 87 to about 93, from about 85 to about 93, or from about 90 to about 92.

Accordingly, as described herein, in some embodiments are methods of using the polishing compositions, where the methods comprise the steps of a) providing the polishing composition described herein; b) providing a substrate, wherein the substrate comprises a carbon (C) containing layer; and c) polishing the substrate with the polishing composition to provide a polished substrate.

As in any embodiment above, a method wherein the substrate is a semiconductor.

As in any embodiment above, a method wherein the substrate further comprises a dielectric film. In one embodiment the dielectric film contains silicon, e.g., amorphous silicon.

As in any embodiment above, a method wherein the Si removal rate (RR) is less than about 92 Å/min.

As in any embodiment above, a method wherein the C removal rate (RR) ranges from about 4800 Å/min to about 7710 Å/min.

As in any embodiment above, a method wherein the carbon removal rate:silicon removal is selectivity is greater than about 80.

As in any embodiment above, a method comprising a substrate contains a carbon hardmask (CHM).

### D. Examples

The following preparations and examples are given to enable those skilled in the art to more clearly understand and to practice the present invention. They should not be considered as limiting the scope of the invention, but merely as being illustrative and representative.

In one aspect, disclosed are methods of making the polishing compositions. In another aspect are disclosed methods of using the polishing compositions to polish materials.

### Example 1: Polishing Conditions

### Materials and Tools Used:

Polishing conditions
Multiprep™ benchtop polisher (Allied High Tech Products Inc.)
Head rotation speed: 22 rpm.
Flow rate: 50 mL/min.
Down force: 1 psi
Polishing time: 60 sec.
Pad: OPTIVISION™ PRO 9500 pads (DuPont)

### Example 2: Evaluation of Various Polishing Compositions

For this study, Comparative Slurries 1-3 (Comp. 1-3) and Exemplary Slurries 1 and 2 were prepared to determine the effects each component of the disclosed polishing slurries have on the C removal rate (RR). Table 1 shows that polishing slurries with no anionic surfactant (i.e., Comp. 1-3) exhibit a lower C removal rate (RR) compared to a polishing slurry that contains anionic surfactant (i.e., Example Slurry 1,2).

TABLE 1
Composition of Slurries Comparative Examples 1-3 and Examples 1-2

| | Surfactant | | Salt | | Polymer | | | | | | |
|---|---|---|---|---|---|---|---|---|---|---|---|
| | | Content | | Content | | | Content | | | C/ | Zeta |
| Example° | Structure | [wt. %] | Name | [wt. %] | Name | MW | [wt. %] | CRR* | a-SiRR | a-Si | Potential** |
| Comp. 1 | — | — | — | — | — | — | — | 2006 | 139 | 14.5 | — |
| Comp. 2 | — | — | — | — | PEG | 400 | 0.002 | 2071 | 75 | 27.7 | — |
| Comp. 3 | — | — | Al(NO₃)₃ | 0.2 | PEG | 400 | 0.002 | 1381 | 68 | 20.2 | — |
| 1 | C12 | 0.001 | Al(NO₃)₃ | 0.2 | — | — | — | 8784 | 207 | 42.4 | — |
| | Branched | | | | | | | | | | |
| | Diphenyl | | | | | | | | | | |
| | Oxide | | | | | | | | | | |
| | Disulfonic | | | | | | | | | | |
| | Acid | | | | | | | | | | |
| 2 | C12 | 0.001 | Al(NO₃)₃ | 0.2 | PEG | 400 | 0.002 | 7706 | 84 | 91.6 | 48 |
| | Branched | | | | | | | | | | |
| | Diphenyl | | | | | | | | | | |
| | Oxide | | | | | | | | | | |
| | Disulfonic | | | | | | | | | | |
| | Acid | | | | | | | | | | |

*in [A/min];
**in [mV];
°All slurries contained a cationic modified commercially available colloidal silica (average primary particle size: 90 nm) with a content of 0.05 wt. % and nitric acid as a pH adjuster such that the slurry has a pH of 3.5.

Next. Table 2 shows that the aluminum (III) metal salt provides a higher carbon/silicon selectivity ratio compared to other salts, e.g., calcium nitrate.

TABLE 2
Screening of Salt Forms

| | Surfactant*** | Salt | | Polymer | | | | | | |
|---|---|---|---|---|---|---|---|---|---|---|
| | Content | | Content | | | Content | | | C/ | Zeta |
| Example | [wt. %] | Name | [wt. %] | Name | MW | [wt. %] | CRR* | a-SiRR | a-Si | Potential** |
| Comp. 4 | 0.001 | Ca(NO₃)₂ | 0.2 | PEG | 400 | 0.002 | 976 | 57 | 17.2 | — |
| 2 | 0.001 | Al(NO₃)₃ | 0.2 | PEG | 400 | 0.002 | 7706 | 84 | 91.6 | 48 |

*in [A/min];
**in [mV];
***the surfactant is a C12 Branched Diphenyl Oxide Disulfonic Acid;
°All slurries contained a cationic modified commercially available colloidal silica (average primary particle size: 90 nm) with a content of 0.05 wt. % and nitric acid as a pH adjuster such that the slurry has a pH of 3.5.

In the next study the effect of several anionic surfactants on the carbon/silicon removal rate selectivity present of the disclosed polishing slurries was determined. Here, Table 3 shows that slurries with an aryl sulfonic acid-containing surfactant as disclosed herein (i.e., Example Slurries 2-5) exhibited a higher carbon/silicon removal rate selectivity compared to Comparative Example 3 (which did not contain such an anionic surfactant). Furthermore, a higher carbon/silicon removal rate selectivity was observed for polishing slurries with an aryl sulfonic acid-containing surfactants.

Specifically, a higher carbon/silicon removal rate selectivity was observed for aryl sulfonic acid-containing surfactants with a tail containing 12 carbons (i.e., Example slurries 2, 4 and 5) compared to aryl sulfonic acid-containing surfactants with a shorter tail (i.e., Example 3). Example slurry 2 containing an aryl sulfonic acid-containing surfactants with a branched 12 carbon tail provided the highest carbon/silicon removal rate selectivity.

TABLE 3
Screening Studies of various anionic surfactants

| | Surfactant | | | | | C/ | Zeta |
|---|---|---|---|---|---|---|---|
| Example° | Structure | Head | Tail | CRR* | a-SiRR | a-Si | Potential** |
| Comp. 3 | — | — | — | 1381 | 68 | 20.2 | — |
| 3 | C6 Branched Diphenyl | 2 | C6 branch | 2588 | 78 | 33.1 | — |
| | Oxide Disulfonic Acid | | | | | | |
| 4 | 4-Dodecylbenzenesulfonic | 1 | C12 linear | 4878 | 67 | 72.7 | — |
| | acid | | | | | | |
| 5 | Linear Alkylbenzene | 1 | C12 linear | 5222 | 77 | 67.9 | — |
| | Sulfonic Acid | | | | | | |
| 2 | C12 Branched Diphenyl | 2 | C12 branch | 7706 | 84 | 91.6 | 48 |
| | Oxide Disulfonic Acid | | | | | | |

*in [A/min];
**in [mV];
°All slurries contained a cationic modified commercially available colloidal silica (average primary particle size: 90 nm) with a content of 0.05 wt. %, a Al(NO₃)₃ salt with a content of 0.2 wt. %, a PEG 400 polymer with a content of 0.002 wt. % , and nitric acid as a pH adjuster such that the slurry has a pH of 3.5.

In the next study, various properties of the abrasive were examined. As a first, the effects of cationic surface modifications on the carbon/silicon removal rate selectivity various of polishing slurries were investigated. Here, Table 4 shows that both polishing slurries containing a non-modified surface (i.e., Example Slurry 6) and a cationically modified surface (i.e., Example Slurries 2 and 10) exhibit a high carbon/silicon removal rate selectivity. The polishing slurry containing a highly cationically modified surface (i.e., more than 4.4% of the abrasive's surface is cationically modified; Comparative Slurry 6) was not used for polishing due to agglomeration of abrasive.

TABLE 4
Effects on cationically modifying the surface of the silica abrasive

| | Abrasive | | | | | | |
|---|---|---|---|---|---|---|---|
| | | % coverage by | | | | C/ | Zeta |
| Example° | Name | cationization | content | CRR* | a-SiRR | a-Si | Potential** |
| Comp. 5 | — | — | — | 1469 | 15 | 92 | — |
| 6 | Unmodified | 0 | 0.05 | 7618 | 87 | 87.3 | 20 |
| | commercially available | | | | | | |
| | colloidal silica (average | | | | | | |
| | primary particle size 90 | | | | | | |
| | nm) | | | | | | |
| 10 | modified commercially | 2.0 | 90 | 7247 | 86 | 84.5 | 34 |
| | available colloidal silica | | | | | | |
| | (average primary | | | | | | |
| | particle size 90 nm) | | | | | | |
| 2 | modified commercially | 4.4 | 0.05 | 7706 | 84 | 91.6 | 48 |
| | available colloidal silica | | | | | | |
| | (average primary | | | | | | |
| | particle size 90 nm) | | | | | | |
| Comp. 6 | modified commercially | more than | 90 | — | — | — | — |
| | available colloidal silica | 4.4 | | | | | |
| | (average primary | | | | | | |
| | particle size 90 nm) | | | | | | |

*in [A/min];
**in [mV];
°All slurries contained a C12 Branched Diphenyl Oxide Disulfonic Acid surfactant with a content of 0.001 wt. %, and nitric acid as a pH adjuster such that the slurry has a pH of 3.5.

Additional studies directed towards varying the extend of the abrasive's surface being cationically modified as well as changes in its primary average particle size showed that both of these parameters can modulate the carbon/silicon removal rate selectivity. Specifically, the data in Table 5 shows that Example Slurry 2 exhibited a higher carbon/silicon removal rate selectivity compared to Exemplary Slurries 7, 8 and 9.

TABLE 5
Effects of surface modification and average primary particle size on carbon and silicon removal rates.

| | Abrasive*** | | | | | | | | | | | |
|---|---|---|---|---|---|---|---|---|---|---|---|---|
| | Average | % | | | | | | | | | | |
| | primary | coverage | aggre- | Salt | | Polymer | | | | | | |
| | particle | by cation- | gation | | Content | | | Content | | | C/ | Zeta |
| Example° | size (nm) | ization | ratio | Name | [wt. %] | Name | MW | [wt. %] | CRR* | a-SiRR | a-Si | Potential** |
| Comp. 5 | — | — | — | Al(NO₃)₃ | 0.2 | PEG | 400 | 0.002 | 1469 | 15 | 92 | — |
| 7 | 24 | 2.5 | 2.00 | Al(NO₃)₃ | 0.2 | PEG | 400 | 0.002 | 4838 | 69 | 70.0 | — |
| 8 | 35 | 2.4 | 1.94 | Al(NO₃)₃ | 0.2 | PEG | 400 | 0.002 | 5955 | 75 | 79.7 | — |
| 9 | 78 | 4.6 | 1.55 | Al(NO₃)₃ | 0.2 | PEG | 400 | 0.002 | 5786 | 108 | 53.6 | — |
| 2 | 90 | 4.4 | 2.42 | Al(NO₃)₃ | 0.2 | PEG | 400 | 0.002 | 7706 | 84 | 91.6 | 48 |

*in [A/min];
**in [mV];
***a cationic modified commercially available colloidal silica;
°All slurries contained a C12 Branched Diphenyl Oxide Disulfonic Acid surfactant with a content of 0.001 wt. %, and nitric acid as a pH adjuster such that the slurry has a pH of 3.5.

Next, Table 6 below shows that the carbon/silicon removal rate selectivity can also be modulated with the amount of cationic modified abrasive present in the polishing slurry. Specifically, Table 6 shows that a general decrease in carbon/silicon removal rate selectivity can be observed as the amount of abrasive is increased (i.e., Example Slurries 2 and 12 versus Example Slurry 11). However, an increase in the carbon removal rate and silicon removal rate is observed as the amount of cationic modified abrasive increases.

TABLE 6
Effects of the amount of abrasive on carbon and silicon removal rates.

| | Abrasive*** | Salt | | Polymer | | | | | | |
|---|---|---|---|---|---|---|---|---|---|---|
| | Content | | Content | | | Content | | | C/ | Zeta |
| Example° | [wt. %] | Name | [wt. %] | Name | MW | [wt. %] | CRR* | a-SiRR* | a-Si | Potential** |
| Comp. 5 | | Al(NO₃)₃ | 0.2 | PEG | 400 | 0.002 | 1469 | 15 | 92 | — |
| 11 | 0.01 | Al(NO₃)₃ | 0.2 | PEG | 400 | 0.002 | 5990 | 52 | 116.3 | — |
| 2 | 0.05 | Al(NO₃)₃ | 0.2 | PEG | 400 | 0.002 | 7706 | 84 | 91.6 | 48 |
| 12 | 0.1 | Al(NO₃)₃ | 0.2 | PEG | 400 | 0.002 | 7941 | 89 | 89.1 | — |

*in [A/min];
**in [mV];
***Commercially available colloidal silica (average primary particle size: 90 nm) with a % coverage by cationizaton of 4.4;
°All slurries contained a C12 Branched Diphenyl Oxide Disulfonic Acid surfactant with a content of 0.001 wt. % and nitric acid as a pH adjuster such that the slurries has a pH of 3.5.

In the last study, the effects of the pH of the polishing slurry on carbon/silicon removal rates were examined. Here, Table 7 shows that the removal rates of silicon and carbon generally decrease as the pH increases within a pH range of 2-5. Furthermore, a general trend of loss of carbon/silicon removal rate selectivity was observed as a function of pH, i.e., an increase in pH resulted in a decrease in carbon/silicon removal rate selectivity.

TABLE 7
Effects of pH on removal rates of carbon and silicon

| | Salt | | Polymer | | | pH | | | | | |
|---|---|---|---|---|---|---|---|---|---|---|---|
| | | Content | | | Content | adjuster | | | | C/ | Zeta |
| Example° | Name | [wt. %] | Name | MW | [wt. %] | Name | pH | CRR* | a-SiRR | a-SiRR | Potential** |
| 13 | Al(NO₃)₃ | 0.2 | PEG | 400 | 0.002 | HNO3 | 2.0 | 7391 | 62 | 118.8 | — |
| 14 | Al(NO₃)₃ | 0.2 | PEG | 400 | 0.002 | HNO3 | 2.5 | 7734 | 65 | 119.3 | — |
| 15 | Al(NO₃)₃ | 0.2 | PEG | 400 | 0.002 | HNO3 | 3.0 | 7327 | 81 | 90.8 | — |
| 2 | Al(NO₃)₃ | 0.2 | PEG | 400 | 0.002 | HNO3 | 3.5 | 7706 | 84 | 91.6 | 48 |
| 16 | Al(NO₃)₃ | 0.2 | PEG | 400 | 0.002 | HNO3 | 4.0 | 4022 | 102 | 39.5 | — |
| 17 | Al(NO₃)₃ | 0.2 | PEG | 400 | 0.002 | HNO3 | 4.5 | 3802 | 153 | 24.9 | — |
| Comp. 7 | Al(NO₃)₃ | 0.2 | PEG | 400 | 0.002 | HNO3 | 5.0 | — | — | — | — |

*in [A/min];
**in [mV];
°All slurries contained a cationic modified commercially available colloidal silica abrasive with a content of 0.05 wt. % and a C12 Branched Diphenyl Oxide Disulfonic Acid surfactant with a content of 0.001 wt. %

It will be apparent to those skilled in the art that various modifications and variations can be made in the present invention without departing from the scope or spirit of the invention. Other aspects of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A polishing composition comprising a silica abrasive, an anionic surfactant, an aluminum (Al) salt, and water, wherein
the anionic surfactant is an arylsulfonic acid-containing surfactant; and
the Al salt comprises an aluminum nitrate salt, an aluminum sulfate salt or an aluminum halide salt,
wherein the polishing composition has a pH ranging from about 1.0 to about 4.5.

2. The polishing composition of claim 1, wherein the Al salt is selected from the group consisting of aluminum (III) nitrate, aluminum (III) chloride and aluminum (III) sulfate.

3. The polishing composition of claim 1, wherein the Al salt is present in a concentration ranging from about 0.1 wt. % to about 1.0 wt. %.

4. The polishing composition of claim 1, wherein the anionic surfactant is an arylsulfonic acid-containing surfactant of Formula (I): 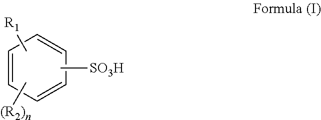
wherein
R₁ is a C₅-C₂₀ alkyl group;
R₂, in each instance, is selected from the group consisting of —SO₃H and 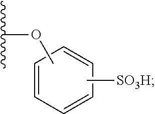
and
n is an integer selected from 0, 1, or 2.

5. The polishing composition of claim 4, wherein R₁ is a C₆-C₁₆ alkyl group.

6. The polishing composition of claim 5, wherein n is 1.

7. The polishing composition of claim 6, wherein R₂ is

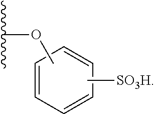

8. The polishing composition of claim 1, wherein the silica abrasive is a cationic-surface modified silica abrasive, wherein the cationic-surface modified abrasive has at least about 2% of its surface area modified.

9. The polishing composition of claim 1, wherein the silica abrasive has an average primary particle size ranging from about 20 nm to about 90 nm.

10. The polishing composition of claim 1, wherein the silica abrasive is present in the polishing composition at a concentration ranging from about 0.01 wt. % to about 0.1 wt. %.

11. The polishing composition of claim 1, wherein the silica abrasive has a positive zeta potential ranging from about 20 mV to about 50 mV in the polishing composition.

12. The polishing composition of claim 1 further comprising a water-soluble polymer and/or a pH-adjusting agent.

13. The polishing composition of claim 12, wherein the water-soluble polymer is a poly(ethylene glycol) (PEG) polymer or a polyvinylpyrrolidone (PVP) polymer, wherein the water-soluble polymer is present in a concentration ranging from about 0.001 wt. % to about 0.003 wt. %.

14. The polishing composition of claim 12, wherein the pH-adjusting agent is nitric acid.

15. A polishing composition comprising a silica abrasive, an anionic surfactant, an aluminum (Al) salt, and water, wherein
the anionic surfactant is present at a concentration ranging from about 0.001 wt. % to about 0.01 wt. % and is an arylsulfonic acid-containing surfactant selected from the group consisting of 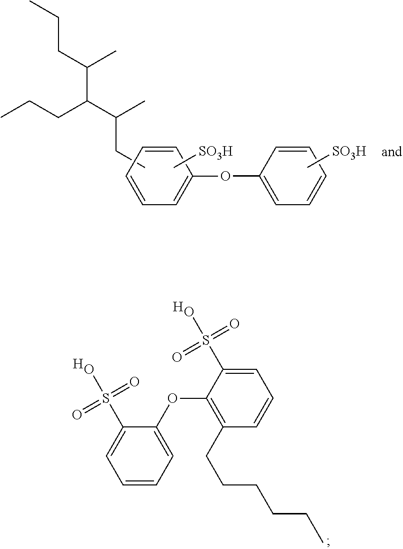
the Al salt is present at a concentration ranging from about 0.15 wt. % to about 0.25 wt. % and is selected from the group consisting of an aluminum (III) nitrate salt, an aluminum (III) sulfate salt or an aluminum (III) chloride salt; and
the silica abrasive is a cationic-surface modified abrasive with an average primary particle size ranging from about 85 nm to about 95 nm and a zeta potential ranging between 45 and 50 mV;
wherein the polishing composition has a pH ranging from about 2.0 to about 3.5.

16. The polishing composition of claim 15 further comprising a PEG 400 polymer in an amount ranging from about 0.001 wt. % to about 0.003 wt. %.

17. The polishing composition of claim 15, wherein the composition has a carbon removal rate of at least about 2500 nm; and/or has a silicon removal rate of less than about 150 nm; and/or has a carbon removal rate:silicon removal rate selectivity ratio of greater than 50.

18. A method for polishing a substrate, the method comprising the steps of:
(a) providing a polishing composition of claim 1;
(b) providing a substrate, wherein the substrate comprises a carbon-containing layer; and
(c) polishing the substrate with the polishing composition to provide a polished substrate.

19. The method of claim 18, wherein the substrate further comprises a dielectric film containing amorphous silicon.

20. The method of claim 18, wherein the method has a carbon removal rate ranging from about 4800 Å/min to about 7710 Å/min; and/or has a silicon removal rate of less than about 92 Å/min; and/or has a carbon removal rate:silicon removal rate selectivity of greater than 80.

21. The method of claim 18, wherein the substrate is a carbon hardmask (CHM).
